(19) United States
(12) Patent Application Publication
(10) Pub. No.: US 2020/0249588 A1
(43) Pub. Date: Aug. 6, 2020

(54) ADHESIVE RESIDUE REMOVAL APPARATUS AND ADHESIVE RESIDUE REMOVAL METHOD

(71) Applicant: MICRO ENGINEERING, INC., Tokyo (JP)

(72) Inventors: Kazuya WATANABE, Kanagawa (JP); Hajime TOMIZAWA, Tokyo (JP); Shuichi NOZAWA, Tokyo (JP)

(21) Appl. No.: 16/265,039

(22) Filed: Feb. 1, 2019

(51) Int. Cl. G03F 7/20; B08B 7/00

(52) U.S. Cl. CPC G03F 7/70925; B08B 2220/01; B08B 7/0035

(57) ABSTRACT

The present invention provides an adhesive residue removal apparatus capable of removing pellicle adhesive residue efficiently without damaging a pattern surface. An adhesive residue removal apparatus for removing organic matter existing as pellicle adhesive residue on a surface of a reticle when a pellicle is separated from the reticle includes a head adapted to generate atmospheric pressure plasma and emit the generated atmospheric pressure plasma to organic matter existing on a surface of a workpiece W; and a control unit adapted to control the atmospheric pressure plasma under irradiation conditions as the atmospheric pressure plasma is emitted from the head to remove the pellicle adhesive residue from the surface of the workpiece.

### BACKGROUND OF THE INVENTION

### Field of the Invention

The present invention relates to a technique for removing adhesive residue on reticles used in manufacturing processes of semiconductors, liquid crystal display panels, and the like.

### Description of the Related Art

In a manufacturing process of a semiconductor, liquid crystal display panel, or the like, patterning is done by irradiating a photosensitive layer or the like with light through a mask (also referred to as a lithography photomask or reticle).

In this process, if foreign matter attaches to the mask, the light will be absorbed or bent by the foreign matter. This poses a problem that a resulting pattern is deformed or edges of the pattern are distorted, spoiling dimensions, quality, appearance, and the like of patterning.

To solve this problem, a method is adopted that inhibits foreign matter from attaching to the surface of the mask by mounting a pellicle on a surface of the mask, the pellicle being a dust cover provided with a pellicle film transparent to light.

The pellicle normally includes a pellicle frame made of metal and a pellicle film placed on one end face of the pellicle frame. A mask adhesive layer is formed on another end face of the pellicle frame to fix the pellicle to the mask. To mount the pellicle on the mask, the mask adhesive layer is fixed to a predetermined position of the mask by crimping.

Also, photoresist is applied, followed by exposure and development processes, to form a resist pattern for use in patterning. In this case, it is necessary to remove the resist that has become unnecessary.

For example, Japanese Patent Publication No. 2008-085231 discloses a residual organic matter removal method for removing organic matter remaining on a surface, where the organic matter includes an altered layer formed on a resist surface by alteration of resist and an unaltered resist layer remaining unaltered under the altered layer. With this method, the unaltered resist layer is removed by dropping an ozone solution or only ozone water onto the unaltered resist layer.

After patterning via a reticle, when a pellicle is separated from the reticle, adhesive deposit (adhesive residue) may remain on the reticle. Under the present circumstances, an adhesive deposit removal process (cleaning process) after separation of the pellicle is a wet process using a chemical solution. Therefore, there is a problem in that repeated chemical solution processes make a reticle surface clouded, resulting in a so-called haze and thereby causing damage to a pattern surface. Consequently, there remains a problem in that a drawing error will occur in a subsequent lithography process.

A main object of the present invention is to provide an adhesive residue removal apparatus capable of removing adhesive residue efficiently without damaging a pattern surface. The present invention also provides an adhesive residue removal method.

### SUMMARY OF THE INVENTION

The present disclosure provides an adhesive residue removal apparatus for removing organic matter existing as pellicle adhesive residue on a surface of a reticle when a pellicle is separated from the reticle, the apparatus comprising: a generating unit adapted to generate atmospheric pressure plasma by converting oxygen contained in harmless gas (clean dry air) into active oxygen radicals at a predetermined pressure around atmospheric pressure or sub-atmospheric pressure; an irradiating unit adapted to emit the generated atmospheric pressure plasma to the organic matter; and a control unit adapted to control the atmospheric pressure plasma under predetermined conditions (irradiation conditions), the atmospheric pressure plasma being emitted to the organic matter by the irradiating unit.

Further features of the present invention will become apparent from the following description of exemplary embodiments (with reference to the attached drawings).

### BRIEF DESCRIPTION OF THE DRAWINGS

FIG. 1 is a schematic plan view showing an exemplary overall configuration of an adhesive residue removal apparatus according to an embodiment of the present invention;

FIG. 2 is a schematic diagram describing a mechanism of adhesive residue removal by atmospheric pressure plasma;

FIG. 3 is a diagram describing a relationship between atmospheric pressure plasma irradiation conditions and processing results (adhesive residue removal results) under the respective conditions.

FIG. 4 is a diagram showing atmospheric pressure plasma irradiation conditions and results of examining whether a pattern surface is damaged.

FIGS. 5A and 5B are partial enlarged views of a workpiece surface before processing and the workpiece surface after processing, respectively.

FIGS. 6A to 6D show examination data obtained by detecting surface roughness of a workpiece surface and checking the presence or absence of pellicle adhesive residue.

FIG. 7 is a flowchart showing an example of major control procedures used by a control unit to perform an adhesive residue removal method.

### DESCRIPTION OF THE EMBODIMENTS

An exemplary embodiment of the present invention will be described below with reference to the accompanying drawings. Note that in the present embodiment, description will be given by taking as an example an adhesive residue removal apparatus for removing organic matter existing as adhesive residue on a surface of a reticle, i.e., an adhesive residue removal apparatus that removes pellicle adhesive residue (which may be simply referred to hereinafter as an adhesive residue) remaining on the reticle using a dry process when a pellicle is separated from the reticle after patterning via the reticle.

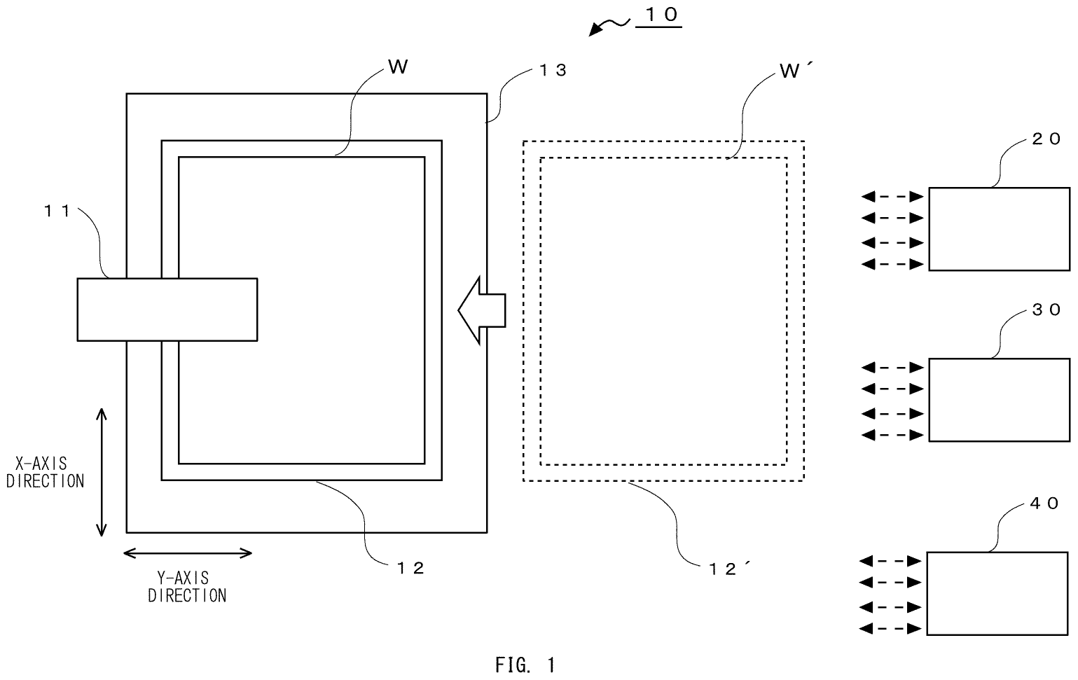

FIG. 1 is a schematic plan view showing an exemplary overall configuration of an adhesive residue removal apparatus according to the present embodiment.

An adhesive residue removal apparatus 10 shown in 1 FIG. includes a head 11 used to irradiate a processing object W (e.g., reticle; hereinafter sometimes referred to as a workpiece W) with atmospheric pressure plasma, a stage 12 on which the workpiece W is placed, a head 11, a table 13 on which the stage 12 is placed, and a control unit 20.

Note that the control unit 20 is a type of computer functioning as a control unit adapted to control components of the adhesive residue removal apparatus 10. Also, the atmospheric pressure plasma may sometimes be referred to as normal pressure plasma.

The adhesive residue removal apparatus 10 also includes an ozone generator 30 and a plasma controller 40, and functions as a generating unit adapted to generate/output atmospheric pressure plasma used to irradiate the workpiece W, in collaboration with the control unit 20. In this way, atmospheric pressure plasma is generated through conversion of oxygen contained in harmless gas (clean dry air) into active oxygen radicals at a predetermined pressure around atmospheric pressure or sub-atmospheric pressure.

The head 11 includes a nozzle (not shown) to direct the generated atmospheric pressure plasma at a surface (surface to be processed) of the workpiece W placed on the stage 12. Note that the head 11 including the nozzle may sometimes be referred to as a plasma irradiating unit.

Also, as shown in FIG. 1, the head 11 is configured to be moveable relatively in each of an X-axis direction and Y axis direction over the table 13. Also, the head 11 is configured to be moveable up and down with respect to the table 13. By moving the head 11 up or down, it is possible to adjust a distance from the plasma irradiating unit to the surface of the workpiece W to be processed to any desired value.

Note that the head 11 is moved in the X-axis direction, Y-axis direction, upward direction, and downward direction, for example, via a non-illustrated drive mechanism. Also, amounts of movement per unit time, total amounts of movement, movement start timings, and the like are mainly controlled by the control unit 20.

The stage 12 is configured to be able to transfer the workpiece W placed thereon to a processing area described later and transfer the processed workpiece W to an unload position. Specifically, the stage 12 is configured to be moveable relatively in each of the X-axis direction and Y axis direction over the table 13.

For example, as shown in FIG. 1, the stage 12 is moved such that a workpiece (workpiece W′ indicated by a broken line) can be set on a stage at a position of the stage 12′ indicated by a broken line. After the workpiece is set, by moving to a position of the stage 12 indicated by a solid line, an adhesive residue removal process is started. Note that an area in which the adhesive residue removal process is started and finished may sometimes be referred to as a processing area.

Also, the stage 12 is configured to be moveable in each of the X-axis direction and Y axis direction relative to the head 11 during the adhesive residue removal process. Also, as with the head 11, the stage 12 may be configured to be moveable up and down.

Note that the stage 12 is moved in the X-axis direction, Y-axis direction, upward direction, and downward direction, for example, via a non-illustrated drive mechanism. Also, amounts of movement per unit time, total amounts of movement, movement start timings, and the like are mainly controlled by the control unit 20.

Also, rather than configuring each of the head 11 and stage 12 to be moveable, it is possible to configure one of the head 11 and stage 12 to be moveable with respect to the table 13.

Also, the adhesive residue removal apparatus 10 includes various sensors for use to detect respective positions (positions relative to the table 13) of the head 11 and stage 12 as well as a camera for use to monitor processing status.

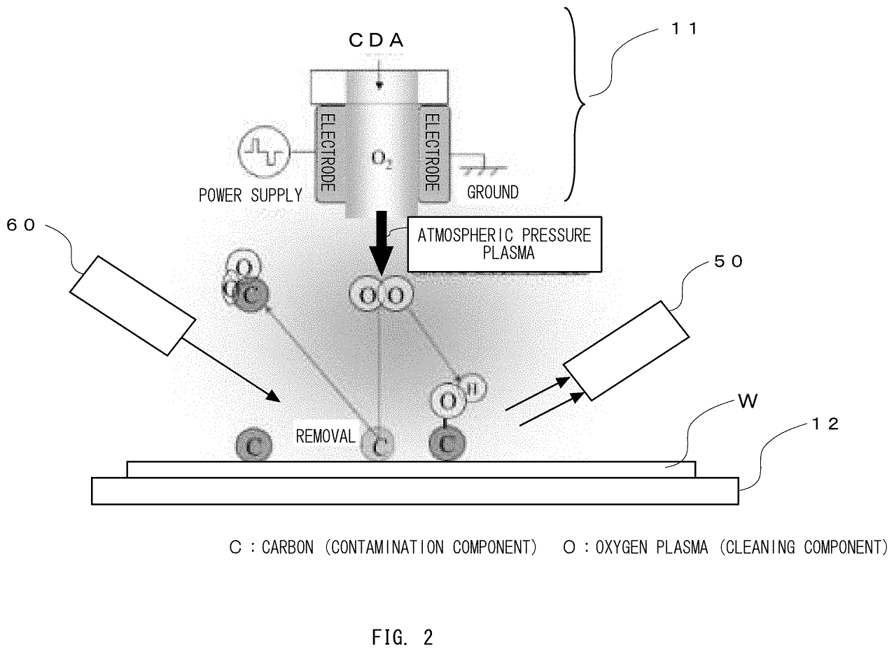

Also, to prevent a pressure-sensitive adhesive sublimated along with the removal process from attaching again to the workpiece, an exhaust unit 50 (see FIG. 2) can be provided in a neighborhood of a plasma treatment area, e.g., in a neighborhood of the workpiece irradiated with atmospheric pressure plasma. The exhaust unit 50 will enable local exhaust whereby gas around the workpiece irradiated with the atmospheric pressure plasma is efficiently discharged outside.

Also, a temperature sensor 60 (see FIG. 2) can be provided to monitor temperature on a reticle surface during plasma treatment.

Note that start and stop of exhaust by the exhaust unit 50, an exhaust volume per unit time, and the like are controlled by the control unit 20. Also, the control unit 20 controls operation of the adhesive residue removal apparatus 10 according to detection results produced by the temperature sensor 60.

### [Irradiation Target]

The adhesive residue removal apparatus 10 according to the present embodiment treats any pressure-sensitive adhesive (organic matter) existing on the surface of the workpiece W as an object of removal. Specific examples include pellicle adhesive residue to be removed from a surface of the workpiece W.

As an adhesive for pellicles, an acrylic pressure-sensitive adhesive or silicone pressure-sensitive adhesive can be used, for example. In particular, the acrylic pressure-sensitive adhesive, which readily provides desired tensile strength and peel strength, can be used suitably. Also, an acrylic pressure-sensitive adhesive containing hardened alkyl (meth)acrylate copolymer may sometimes be used. Let us proceed with the description by citing a concrete example of pressure-sensitive adhesives (organic matter).

A mask adhesive, which is an irradiation target (object to be removed), contains 100 parts by mass of a thermoplastic elastomer (A) with a tangent δ peak temperature of −20 to 30 [° C.] and 20 to 150 parts by mass of a tackifying resin (B). The thermoplastic elastomer (A) is at least one type selected from the group consisting of a styrene-based thermoplastic elastomer, (meth)acrylate ester thermoplastic elastomer, and olefinic thermoplastic elastomer and the tangent δ peak temperature of the mask adhesive is −10 to 30 [° C.].

Also, the mask adhesive may be an adhesive containing a hydrogenated body of a block copolymer having a saturated cyclic hydrocarbon structure such as a styrene-isoprene-styrene triblock copolymer as well as containing a tackifying agent.

Also, the mask adhesive may be a hot melt adhesive containing styrene-ethylene-propylene-styrene triblock copolymer and an aliphatic petroleum resin.

Also, possible mask adhesives include a pressure-sensitive adhesive containing two types of block copolymer having a polymer block made of an alkyl (meth)acrylate as well as containing a tackifying resin such as a (hydrogenated) petroleum resin.

For example, the adhesive residue removal apparatus 10 removes at least one type of pellicle adhesive component selected from the group consisting of an ethyl (meth)acrylate elastomer (product name: “LA-Polymer 2140e” made by Kuraray Co., Ltd.) and (meth)acrylate ester elastomer (product name: “LA-Polymer 2140e” made by Kuraray Co., Ltd.; with a tangent δ peak temperature of −20 [° C.]) and the like.

Note that (meth)acrylate ester thermoplastic elastomer is a polymer containing a constitutional unit stemming from a (meth)acrylate ester.

Besides, the adhesive residue removal apparatus 10 can also remove a mask adhesive which contains 100 parts by mass of a styrenic resin and 35 to 170 parts by mass (both inclusive) of a hardness modifier and in which a phase-separated structure formed by a continuous phase of the styrenic resin and a dispersed phase of the hardness modifier is observed in an electron micrograph, where the hardness modifier contains polypropylene and a propylene elastomer.

Note that the above-mentioned pressure-sensitive adhesives (organic matter) to be removed are strictly exemplary, and the irradiation targets (objects to be removed) are not limited to these adhesives.

Furthermore, the pellicle adhesive component to be removed is more specifically a diblock copolymer or triblock copolymer of methyl poly(meth)acrylate and a (meth)acrylate ester other than the methyl poly(meth)acrylate. Preferably the (meth)acrylate ester other than the methyl poly(meth)acrylate is a monomer capable of forming a side chain having a bulky branch structure in a polymer block such as n-butyl poly(meth)acrylate, 2-ethylhexyl poly(meth)acrylate, and isononyl poly(meth)acrylate.

Of all the pellicle adhesive components described above, the adhesive residue removal apparatus 10 according to the present embodiment achieves an excellent removal effect on n-butyl poly(meth)acrylate.

Besides, the pressure-sensitive adhesives to be removed by the present apparatus include a pressure-sensitive adhesive such as disclosed in WO2012/157759. The pressure-sensitive adhesive, for example, contains an alkyl (meth)acrylate copolymer and a silane compound, and the alkyl (meth)acrylate copolymer is a copolymer of an alkyl (meth)acrylate and a monomer, the alkyl (meth)acrylate having an alkyl group with 4 to 14 carbon atoms, and the monomer having a functional group reactive to at least either of isocyanate groups and epoxy groups.

Besides, the pressure-sensitive adhesives to be removed by the present apparatus include a pressure-sensitive adhesive such as disclosed in WO2014/142125. Examples include a pressure-sensitive adhesive containing a reaction product of an alkyl (meth)acrylate and a multifunctional epoxy compound, the reaction product being used in a pellicle for ArF.

Besides, the pressure-sensitive adhesives to be removed by the present apparatus include a pressure-sensitive adhesive such as disclosed in Japanese Patent Publication No. 2018-21182. Examples include a pressure-sensitive adhesive containing at least an alkyl acrylate copolymer or alkyl methacrylate copolymer and a hardener, which is an epoxy compound or isocyanate compound, the alkyl acrylate copolymer or alkyl methacrylate copolymer containing 90 to 99 mass % of an alkyl acrylate monomer unit or alkyl methacrylate monomer unit and 1 to 10 mass % of a monomer unit reactive to epoxy groups or isocyanate groups.

Note that “(meth)acrylate” means acrylate or methacrylate. For example, the alkyl (meth)acrylate copolymer means an alkyl acrylate copolymer or alkyl methacrylate copolymer.

Also, in relation to all monomer units (repeating units), the alkyl (meth)acrylate copolymer may preferably contain 90 to 99 [mass %] of an alkyl (meth)acrylate monomer unit component and 1 to 10 mass % of a monomer unit component reactive to epoxy groups or isocyanate groups.

Also, the alkyl (meth)acrylate monomer unit component may be selected from monomer units such as methyl (meth)acrylate, ethyl (meth)acrylate, propyl (meth)acrylate, butyl (meth)acrylate, hexyl (meth)acrylate, octyl (meth)acrylate, decyl (meth)acrylate, dodecyl (meth)acrylate, lauryl (meth)acrylate, isopropyl (meth)acrylate, isobutyl (meth) acrylate, isoamyl (meth) acrylate, 2-ethylhexyl (meth)acrylate, isooctyl (meth)acrylate, and isononyl (meth) acrylate.

Also, the monomer unit component reactive to epoxy groups or isocyanate groups may be selected from monomer units such as carboxyl group-containing monomers such as (meth)acrylic acid and hydroxyalkyl group-containing (meth)acrylates such as 2-hydroxyethyl (meth)acrylate. Note that as an alkyl (meth)acrylate copolymer, for example, an acrylic pressure-sensitive adhesive commercially available from Soken Chemical & Engineering Co., Ltd. may be used.

FIG. 2 is a schematic diagram describing a mechanism of adhesive residue removal by atmospheric pressure plasma.

The adhesive residue removal apparatus 10 performs plasma treatment whereby at a pressure around atmospheric pressure or at a sub-atmospheric pressure, harmless gas (CDA: clean dry air) passes through a discharge space (an electrode gap shown in FIG. 2) and converts oxygen (O₂) contained in the clean dry air into ozone (O₃) (ozone gas). The ozone gas contained in plasma is emitted to the surface of the workpiece W through a nozzle of the head 11.

The atmospheric pressure plasma reaching the surface of the workpiece W modifies (carbonizes) the pressure-sensitive adhesive (organic matter) existing on the surface of the workpiece W using the ozone and oxygen plasma and sublimates the pressure-sensitive adhesive. Consequently, the pellicle adhesive residue on the reticle can be removed.

An example of specifications for atmospheric pressure plasma will be described in detail below.

### [Specifications for Atmospheric Pressure Plasma]

Note that the phrase “around atmospheric pressure” means a range of, for example, 1.013×10⁴ to 50.663×10⁴ [Pa]. Furthermore, considering the ease of pressure regulation and simplification of equipment configuration, preferably the range is 1.333×10⁴ to 10.664×10⁴ [Pa] (100 to 800 [Torr]).

Input power per unit area for plasma treatment is preferably in a range of 2 [W/mm²] to 20 [W/mm²], and more preferably in a range of 5 [W/mm²] to 15 [W/mm²].

The reason for the use of these ranges is that if actual input power is too low compared to the input power per unit area in a predetermined range such as described above, decomposition of pellicle adhesive residue does not progress, resulting in reduced efficiency of the removal process. Also, relatively too high input power is undesirable because a substrate becomes hot due to discharge heat and the substrate itself might be damaged. By taking these points into consideration, the above-mentioned input power value per unit area is set.

Frequency for use in generating a plasma discharge is set, for example, to a value in a range of 10 [kHz] to 3 [GHz]. Furthermore, the frequency is preferably set to a value in a range of 35 [kHz] to 2.5 [GHz], and more preferably to a value in a range of 13.56 [MHz] to 2.4 [GHz].

The reason for the use of these ranges is that if actual frequency is too low compared to the frequency in a predetermined range such as described above, decomposition of pellicle adhesive residue does not progress, but if adjustments are made by increasing the input power to facilitate decomposition, electrolytic damage might be caused to the substrate. On the other hand, relatively too high frequency is undesirable because the substrate being processed might be damaged due to high temperature. By taking these points into consideration, the above-mentioned frequency value is set.

The type of harmless gas used in the removal process is not specified in particular as long as the gas is decomposed by plasma. Examples include clean dry air (dry air), nitrogen, argon, helium, carbon dioxide, carbon monoxide, and fluorine-containing gas. A liquid may also be used if the liquid can be gasified by heating or the like. Specifically, examples include water and alcohols.

Note that the actual removal process is mainly configured as an organic decomposition process that uses oxygen, but a discharge scheme, electrode shape, and the like can be set as desired without any particular restriction. Examples include a scheme whereby a discharge is generated by applying a voltage between a pair of electrodes and a scheme whereby a discharge is emitted into the atmosphere by applying a voltage to a single spot. Also, the electrode shape is not specified in particular, and the voltage may be applied between a pair of parallel flat plates or between a pair of concentric circular electrodes.

The adhesive residue removal apparatus 10 according to the present embodiment is configured, in terms of specifications for atmospheric pressure plasma emitted to the surface of the workpiece W, such that, for example, microwave output applied to the discharge space will be 7.5 [W/mm²], 9.5 [W/mm²], 11.9 [W/mm²], or the like. Also, a plasma jet diameter for emission through the nozzle of the head 11 is, for example, 4 [mm].

Note that in the present embodiment, three types of microwave output pattern are illustrated as an example.

For example, when there is a larger amount of adhesive deposit than usual, i.e., when the adhesive residue is larger in thickness, the input power to plasma per unit area is reduced. Besides apparatus operation is controlled such that irradiation scans described later will be increased a little in number or irradiation scanning speed will be decreased. This makes it possible to remove pellicle adhesive residues neatly without damaging the pattern surface on the workpiece surface.

On the other hand, for example, when there is a smaller amount of adhesive deposit than usual, i.e., when the adhesive residue is smaller in thickness, the input power to plasma per unit area is increased. Consequently, pellicle adhesive residue can be removed efficiently while reducing processing time by controlling apparatus operation such that the number of scans will be decreased.

Determination as to whether there is a larger or smaller amount of adhesive deposit than usual is made in a relative sense by comparing removal conditions with pre-established standard removal conditions including, for example, a plasma output value, the number of scans, and scan speed needed to remove a certain amount of adhesive deposit.

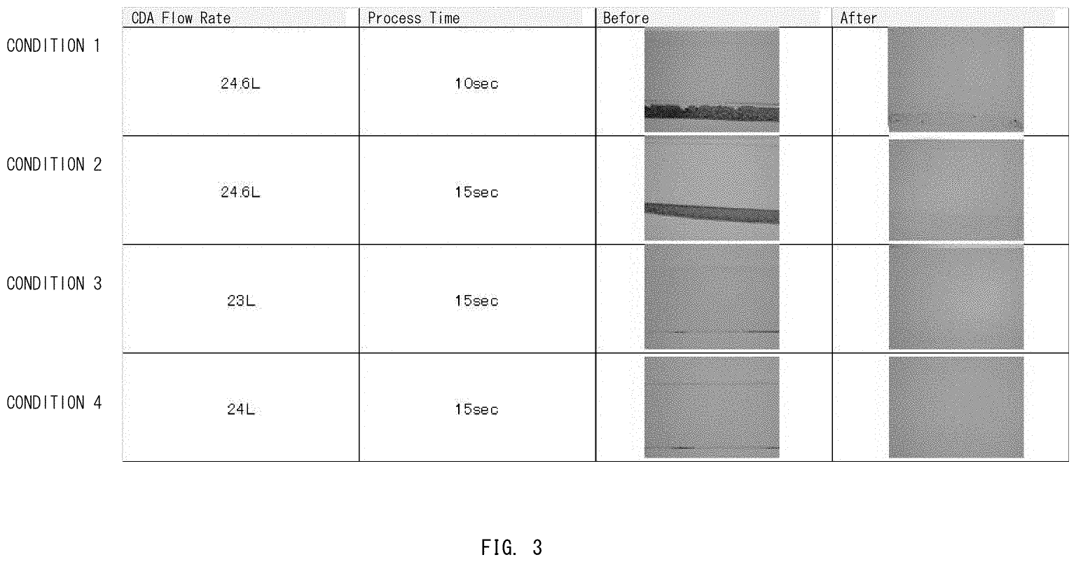

FIG. 3 is a diagram describing a relationship between atmospheric pressure plasma irradiation conditions and processing results (adhesive residue removal results) under the respective conditions.

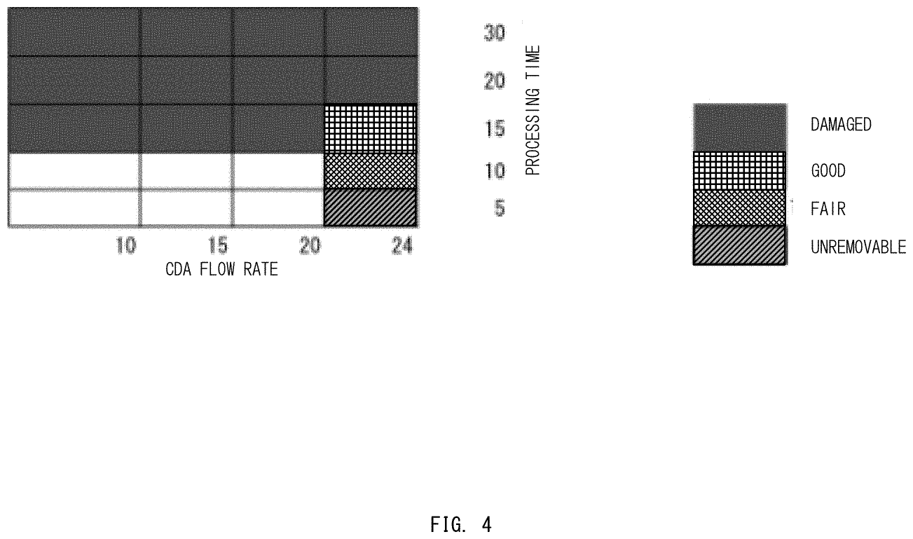

Also, FIG. 4 is a diagram showing atmospheric pressure plasma irradiation conditions and results of examining whether a pattern surface is damaged.

Under various atmospheric pressure plasma irradiation conditions, the present inventor examined adhesive residue removal results as well as whether a pattern surface was damaged.

Regarding the irradiation conditions used in the examination, the surface of the workpiece W was irradiated with atmospheric pressure plasma by varying an air flow rate (CDA flow rate) per unit time, irradiation height (distance from the plasma irradiating unit (e.g., a nozzle tip) to the surface of the workpiece W), and irradiation time (processing time).

Regarding the “irradiation time” according to the present embodiment, for example, when the pellicle adhesive residue existing on the workpiece W is linear and the plasma jet diameter is 4 [mm], it is said that “the irradiation time is 10 [sec]” if 4 [mm] out of the total length of the line is irradiated for 10 [sec].

FIG. 3 shows examination results by taking up patterns examined under irradiation conditions 1 to 4 out of all examined patterns. Note that in all conditions 1 to 4, irradiation height is 6 [mm].

The amount of adhesive deposit remaining on the reticle when the pellicle is separated from the reticle, i.e., the thickness of the adhesive residue, may vary with various factors. Therefore, in the present examination, when the adhesive residue is thick, processing is performed by reducing the input power to plasma per unit area and thereby increasing the irradiation time, and when the adhesive residue is thin, processing is performed in short time and with a small number of scans by increasing the input power to plasma per unit area.

Under condition 1 in FIG. 3, examination results were obtained at a CDA flow rate of 24.6 [L/min] and with a processing time of 10 [sec].

The linear pellicle adhesive residue existing on the workpiece W yet to be processed was changed by processing under condition 1 to the pellicle adhesive residue on the processed workpiece W. When surface conditions of the processed workpiece W are compared with surface conditions of the workpiece W yet to be processed, it can be seen that although the pellicle adhesive residue was removed by the processing under condition 1, some of the pellicle adhesive residue remained unremoved.

Under condition 2 in FIG. 3, examination results were obtained at a CDA flow rate of 24.6 [L/min] and with a processing time of 15 [sec].

The linear pellicle adhesive residue existing on the workpiece W yet to be processed was changed by processing under condition 2 to the pellicle adhesive residue on the processed workpiece W. When surface conditions of the processed workpiece W are compared with surface conditions of the workpiece W yet to be processed, it can be seen that the pellicle adhesive residue was removed by the processing under condition 2.

Also, when compared with the processing results obtained under condition 1, it can be seen that a larger amount of pellicle adhesive residue was removed as a whole in the processing under condition 2.

Under condition 3 in FIG. 3, examination results were obtained at a CDA flow rate of 23 [L/min] and with a processing time of 15 [sec].

The linear pellicle adhesive residue existing on the workpiece W yet to be processed was changed by processing under condition 3 to the pellicle adhesive residue on the processed workpiece W. When surface conditions of the processed workpiece W are compared with surface conditions of the workpiece W yet to be processed, it can be seen that the pellicle adhesive residue was removed by the processing under condition 3.

Under condition 4 in FIG. 3, examination results were obtained at a CDA flow rate of 24 [L/min] and with a processing time of 15 [sec].

The linear pellicle adhesive residue existing on the workpiece W yet to be processed was changed by processing under condition 4 to the pellicle adhesive residue on the processed workpiece W. When surface conditions of the processed workpiece W are compared with surface conditions of the workpiece W yet to be processed, it can be seen that the pellicle adhesive residue was removed by the processing under condition 4.

As shown in FIG. 3, the pellicle adhesive residues on the workpieces W are not necessarily the same due to individual differences among the pellicles and depending on the separation method. Also, as shown in FIG. 4, the pattern surface may be damaged depending on what irradiation conditions are set.

Therefore, based on results of examinations conducted under conditions 1 to 4 described above and other conditions, desirably irradiation conditions are set at least in the following ranges: CDA flow rate: 20 to 24 [L/min]; distance from the plasma irradiating unit to the workpiece W: 6 to 7 [mm]; and irradiation time: 10 to 15 [sec].

Also, if set values of the irradiation conditions for the adhesive residue removal apparatus 10 are included in the above range, even if there is some variation in pellicle adhesive residue among individual workpieces, the pellicle adhesive residue can be removed sufficiently without damaging the pattern surface. This eliminates the need to set irradiation conditions on a workpiece by workpiece basis and makes it possible to improve efficiency of adhesive residue removal.

Note that in the case of automatic control whereby an irradiation point is moved by moving the head 11 or stage 12, the irradiation scanning speed with respect to the linear pellicle adhesive residue existing on the workpiece W is set to any desired value in a range of 1 to 5 [mm/sec].

For example, the value of the irradiation scanning speed is set to 1 [mm/sec] (low speed) when the adhesive residue is thick, and set to 5 [mm/sec] (high speed) when the adhesive residue is thin.

Note that the setting range (1 to 5 [mm/sec]) of the irradiation scanning speed is exemplary and is not restrictive.

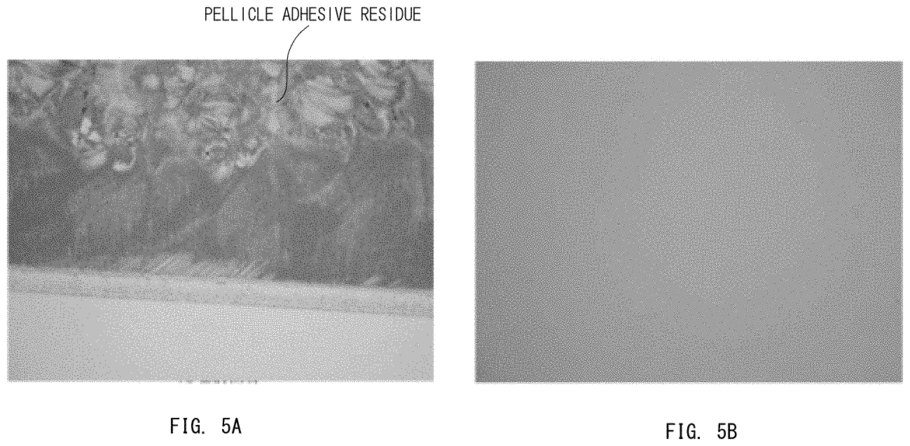

FIGS. 5A and 5B are partial enlarged views of a workpiece surface before processing (FIG. 5A) and the workpiece surface after processing (FIG. 5B), respectively. Note that FIG. 5B shows pellicle adhesive residue removal results obtained under the following atmospheric pressure plasma irradiation conditions: CDA flow rate: 24.6 [L/min]; processing time: 15 [sec]; and irradiation height: 7 [mm].

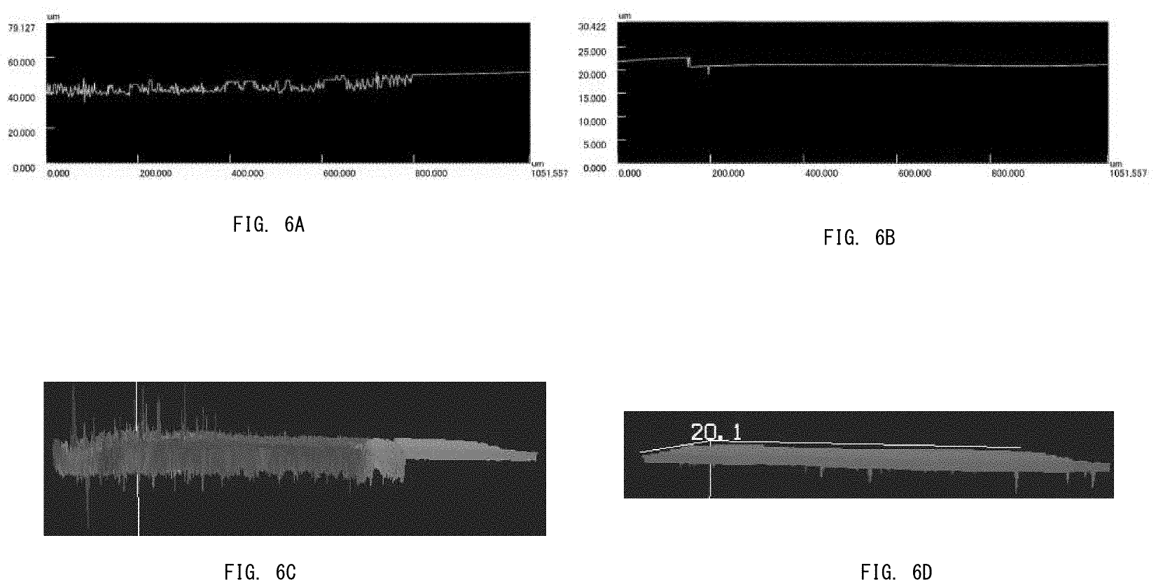

Also, FIGS. 6A to 6D show examination data obtained by detecting surface roughness of a workpiece surface and checking the presence or absence of pellicle adhesive residue, where FIG. 6A is measured data of the workpiece surface before processing, FIG. 6B is measured data of the workpiece surface after processing, FIG. 6C is a 3D image of the workpiece surface before processing, and FIG. 6D is a 3D image of the workpiece surface after processing.

Note that in FIGS. 6A and 6B, the ordinate represents the height [μm] of adhesive residue while the abscissa represents the length [μm] of linear pellicle adhesive residue. Also, the workpiece surface was checked using 5× lens VK-9700 made by Keyence Corporation.

In FIG. 5A, it can be seen that there is pellicle adhesive residue (upper ⅔ of FIG. 5A) on the surface of the workpiece W. Also, in FIG. 5B, it can be seen that the pellicle adhesive residue on the surface of the workpiece W has been removed.

In FIGS. 6A to 6D, the surface roughness of the workpiece surface before and after the processing was detected in a range of the pellicle adhesive residue length of 1051 [μm].

In the measurement results of the workpiece surface before processing shown in FIG. 6A, the height difference of the pellicle adhesive residue in the range of the length of the pellicle adhesive residue was 12.251 [μm] and the average thickness of the adhesive residue was 45.141 [μm]. A 3D image of the workpiece surface at this time is shown in FIG. 6C.

Also, in the measurement results of the workpiece surface after processing shown in FIG. 6B, the height difference of the pellicle adhesive residue in the range of the length of the pellicle adhesive residue was 0.691 [μm] and the average thickness of the adhesive residue was 20.1 [μm]. A 3D image of the workpiece surface at this time is shown in FIG. 6D. Note that “20.1” in FIG. 6D means that the average thickness of the adhesive residue was 20.1 [μm].

Thus, it can be seen that the method according to the present embodiment described so far removes the pellicle adhesive residue sufficiently without damaging the pattern surface and improves the surface roughness of the workpiece surface.

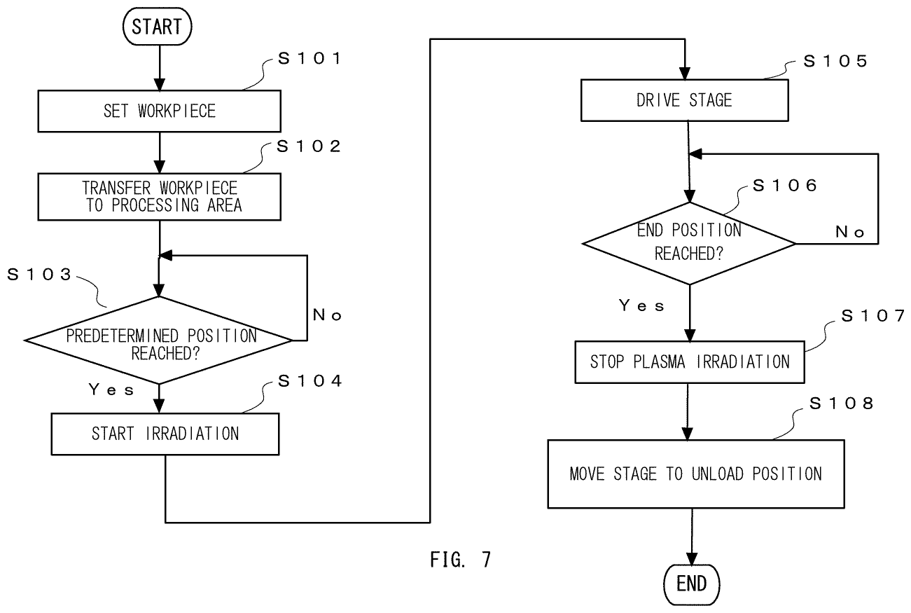

FIG. 7 is a flowchart showing an example of major control procedures used by the control unit 20 to perform an adhesive residue removal method.

The control unit 20 starts control upon receiving input of a start command from an operator of the adhesive residue removal apparatus 10. Note that description will be given by assuming that irradiation conditions and the like have been set in advance.

The control unit 20 makes sure that a workpiece W is placed (set) on the stage 12 (S101).

The control unit 20 transfers the workpiece W to the processing area by moving the stage 12 (S102). For example, the workpiece W is set up at the position of the stage 12 indicated by a broken line in FIG. 1 and then the stage 12 is moved in the direction of the arrow in FIG. 1 to the position of the stage 12 indicated by a solid line, thereby completing the transfer of the workpiece W to the processing area. That is, when the adhesive residue removal process is performed at a place different from the place where the workpiece W is set on the stage 12, the place where the adhesive residue removal process is performed is the processing area.

The control unit 20 determines whether the workpiece W has reached a predetermined position in the processing area, e.g., a start position of irradiation with atmospheric pressure plasma (S103).

If it is determined that the workpiece W has reached the predetermined position (S103: Yes), the control unit 20 starts irradiation with atmospheric pressure plasma (S104).

The control unit 20 drives the stage 12 (or head 11) based on the irradiation conditions (S105). When the position of the head 11 is fixed, the control unit 20 moves the stage 12 toward the linear pellicle adhesive residue existing on the workpiece W (an X-axis direction, Y-axis direction (see FIG. 1)) at a speed corresponding to the irradiation scan speed included in the irradiation conditions.

Note that control may be performed in such a way as to move the head 11 toward the linear pellicle adhesive residue existing on the workpiece W (an X-axis direction, Y-axis direction (see FIG. 1)) by restricting movement of the stage 12 during a period from the start to the end of the irradiation with the atmospheric pressure plasma. Also, control may be performed in such a way as to move both the head 11 and stage 12 to remove the linear pellicle adhesive residue existing on the workpiece W.

The control unit 20 determines whether the workpiece W has reached the end position of irradiation with the atmospheric pressure plasma (S106).

If it is determined that the workpiece W has reached the end position (S106: Yes), the control unit 20 finishes the irradiation with the atmospheric pressure plasma (S107).

The control unit 20 moves the stage 12 to an unload position (removal position of the workpiece W after processing) (S108).

In this way, the adhesive residue removal apparatus according to the present embodiment can remove pellicle adhesive residue sufficiently without damaging the pattern surface using a dry process for irradiation with atmospheric pressure plasma based on set irradiation conditions.

The embodiment described above is intended to describe the present invention more specifically, and the scope of the present invention is not limited to the illustrated examples.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An adhesive residue removal apparatus for removing organic matter existing as pellicle adhesive residue on a surface of a reticle when a pellicle is separated from the reticle, the apparatus comprising:
a generating unit adapted to generate atmospheric pressure plasma by converting oxygen contained in harmless gas (clean dry air) into active oxygen radicals at a predetermined pressure around atmospheric pressure or sub-atmospheric pressure;
an irradiating unit adapted to emit the generated atmospheric pressure plasma to the organic matter; and
a control unit adapted to control the atmospheric pressure plasma under predetermined conditions (irradiation conditions), the atmospheric pressure plasma being emitted to the organic matter by the irradiating unit.

2. The adhesive residue removal apparatus according to claim 1, further comprising a drive mechanism adapted to adjust a distance from a place from which the atmospheric pressure plasma is emitted by the irradiating unit to the organic matter, wherein
the conditions include at least a flow rate of the harmless gas (clean dry air) per unit time, the distance from the place from which the atmospheric pressure plasma is emitted by the irradiating unit to the organic matter, and an irradiation time for which the atmospheric pressure plasma is emitted by the irradiating unit, and the control unit controls emission of the atmospheric pressure plasma under the conditions, the atmospheric pressure plasma being emitted by the irradiating unit.

3. The adhesive residue removal apparatus according to claim 2, wherein the control unit performs control such that the flow rate of the harmless gas (clean dry air) per unit time is in a range of 3 [L/min] to 5000[L/min].

4. The adhesive residue removal apparatus according to claim 2, wherein the control unit performs control such that the distance from the place from which the atmospheric pressure plasma is emitted by the irradiating unit to the organic matter is in a range of 6 [mm] to 7 [mm].

5. The adhesive residue removal apparatus according to claim 2, wherein the control unit performs control such that the irradiation time for which the atmospheric pressure plasma is emitted by the irradiating unit is in a range of 10 [sec] to 15 [sec].

6. The adhesive residue removal apparatus according to claim 1, wherein the organic matter to be removed includes at least one selected from the group consisting of an ethyl (meth)acrylate elastomer, a (meth)acrylate ester elastomer, a mask adhesive and the like, the mask adhesive containing 100 parts by mass of a styrenic resin and 35 to 170 parts by mass (both inclusive) of a hardness modifier (B), the hardness modifier containing polypropylene (b1) and a propylene elastomer, where a phase-separated structure formed by a continuous phase of the styrenic resin and a dispersed phase of the hardness modifier is observed in an electron micrograph of the mask adhesive.

7. The adhesive residue removal apparatus according to claim 6, wherein the harmless gas is clean dry air.

8. The adhesive residue removal apparatus according to claim 1, wherein a component of the organic matter to be removed is n-butyl poly(meth)acrylate.

9. The adhesive residue removal apparatus according to claim 8, wherein the harmless gas is clean dry air.

10. An adhesive residue removal method for removing adhesive residue remaining on a reticle when a pellicle is separated from the reticle, the method comprising:
generating atmospheric pressure plasma by converting oxygen contained in harmless gas (clean dry air) into active oxygen radicals at a predetermined pressure around atmospheric pressure or sub-atmospheric pressure; and
emitting the generated atmospheric pressure plasma to the organic matter based on predetermined conditions (irradiation conditions).

11. The adhesive residue removal apparatus according to claim 2, wherein the organic matter to be removed includes at least one selected from the group consisting of an ethyl (meth)acrylate elastomer, a (meth)acrylate ester elastomer, a mask adhesive and the like, the mask adhesive containing 100 parts by mass of a styrenic resin and 35 to 170 parts by mass (both inclusive) of a hardness modifier (B), the hardness modifier containing polypropylene (b1) and a propylene elastomer, where a phase-separated structure formed by a continuous phase of the styrenic resin and a dispersed phase of the hardness modifier is observed in an electron micrograph of the mask adhesive.

12. The adhesive residue removal apparatus according to claim 3, wherein the organic matter to be removed includes at least one selected from the group consisting of an ethyl (meth)acrylate elastomer, a (meth)acrylate ester elastomer, a mask adhesive and the like, the mask adhesive containing 100 parts by mass of a styrenic resin and 35 to 170 parts by mass (both inclusive) of a hardness modifier (B), the hardness modifier containing polypropylene (b1) and a propylene elastomer, where a phase-separated structure formed by a continuous phase of the styrenic resin and a dispersed phase of the hardness modifier is observed in an electron micrograph of the mask adhesive.

13. The adhesive residue removal apparatus according to claim 4, wherein the organic matter to be removed includes at least one selected from the group consisting of an ethyl (meth)acrylate elastomer, a (meth)acrylate ester elastomer, a mask adhesive and the like, the mask adhesive containing 100 parts by mass of a styrenic resin and 35 to 170 parts by mass (both inclusive) of a hardness modifier (B), the hardness modifier containing polypropylene (b1) and a propylene elastomer, where a phase-separated structure formed by a continuous phase of the styrenic resin and a dispersed phase of the hardness modifier is observed in an electron micrograph of the mask adhesive.

14. The adhesive residue removal apparatus according to claim 5, wherein the organic matter to be removed includes at least one selected from the group consisting of an ethyl (meth)acrylate elastomer, a (meth)acrylate ester elastomer, a mask adhesive and the like, the mask adhesive containing 100 parts by mass of a styrenic resin and 35 to 170 parts by mass (both inclusive) of a hardness modifier (B), the hardness modifier containing polypropylene (b1) and a propylene elastomer, where a phase-separated structure formed by a continuous phase of the styrenic resin and a dispersed phase of the hardness modifier is observed in an electron micrograph of the mask adhesive.

15. The adhesive residue removal apparatus according to claim 2, wherein a component of the organic matter to be removed is n-butyl poly(meth)acrylate.

16. The adhesive residue removal apparatus according to claim 3, wherein a component of the organic matter to be removed is n-butyl poly(meth)acrylate.

17. The adhesive residue removal apparatus according to claim 4, wherein a component of the organic matter to be removed is n-butyl poly(meth)acrylate.

18. The adhesive residue removal apparatus according to claim 5, wherein a component of the organic matter to be removed is n-butyl poly(meth)acrylate.
